(19) United States
(12) Patent Application Publication
(10) Pub. No.: US 2015/0021164 A1
(43) Pub. Date: Jan. 22, 2015

(54) SPUTTERING DEVICE AND METHOD FOR PRODUCING LONG FILM WITH THIN LAYER

(71) Applicant: NITTO DENKO CORPORATION, Osaka (JP)

(72) Inventors: Tomotake Nashiki, Osaka (JP); Akira Hamada, Osaka (JP)

(73) Assignee: NITTO DENKO CORPORATION, Osaka (JP)

(21) Appl. No.: 14/331,476

(22) Filed: Jul. 15, 2014

(30) Foreign Application Priority Data
Jul. 19, 2013 (JP) 2013-150055

(51) Int. Cl. H01J 37/32; C23C 14/34

(52) U.S. Cl. CPC H01J 37/32733; C23C 14/34
USPC 204/192.1; 204/298.24

(57) ABSTRACT

A sputtering device includes: a vacuum chamber; a vacuum pump for evacuating the vacuum chamber; a supply roll for supplying a long film; a storage roll for storing the long film; a film depositing roll that is provided in the vacuum chamber and conveys the long film along a surface thereof; a target facing the film depositing roll; a gas pipe for supplying a gas into the vacuum chamber; a plurality of guide rolls for guiding the long film; a plurality of guide roll shafts provided at each of both ends of the plurality of guide rolls; a plurality of bearings for supporting the guide roll shafts; and a plurality of insulators configured to insulate the guide roll shafts and the bearings from each other, wherein contact surfaces of the guide rolls with the long film are kept at a floating potential.

### BACKGROUND OF THE INVENTION

1. Field of the Invention

The present invention relates to a sputtering device that forms a thin layer on a long film, and a method for producing a long film with a thin layer.

2. Description of Related Art

A sputtering method is widely used as a method for forming a thin layer in vacuum. In the sputtering method, plasma of sputtering gas is generated by applying a voltage between a base substrate and a target with the base substrate kept at an anodic potential and the target kept at a cathodic potential in a sputtering gas such as a low-pressure argon gas. Sputtering gas ions in the plasma strike the target, so that a constituent material of the target is driven out. The constituent material of the target, which is driven out, is deposited on the base substrate to form a thin layer.

As a transparent conductive layer, a thin layer of indium-tin-oxide (ITO) is widely used. When a thin layer of an oxide such as indium-tin-oxide (ITO) is formed, a reactive sputtering method is used. In the reactive sputtering method, a reactive gas such as oxygen is supplied in addition to a sputtering gas such as argon. In the reactive sputtering method, a constituent material of a target, which is driven out, reacts with a reactive gas, so that the constituent material of the target, such as an oxide, is formed and deposited on a base substrate.

In a sputtering device, a target and a cathode are usually mechanically and electrically integrated. The base substrate and the target face each other with a predetermined distance therebetween. The sputtering gas and the reactive gas are usually supplied between the base substrate and the target. The sputtering gas and the reactive gas may be supplied separately, or may be supplied in mixture.

In a sputtering device in which the base substrate is a silicon wafer or a glass plate, the base substrate is transferred using a robot arm, a roller conveyor, or the like. When the silicon wafer or the glass plate is charged, charges are removed by an electricity removing apparatus (ion generating apparatus) before the silicon wafer or the glass plate comes into contact with the robot arm or the roller conveyor.

However, when the base substrate is a long film, it is handled differently from the silicon wafer or the glass plate. A sputtering device and a sputtering method for a long film are described in, for example, JP-A-2009-19246. In the case of a long film, it is impossible to form a sputtered layer over the whole of the long film at a time. Accordingly, the long film delivered from a supply roll is guided by a guide roll on the delivery side to a film depositing roll (also referred to as a can roll). The long film is wound around the film depositing roll by less than one round, and the film depositing roll is rotated at a constant speed to cause the long film to run at a constant speed. A film is deposited on a portion of the long film which faces the target. The long film after completion of film deposition is guided by a guide roll on the storage side and wound around a storage roll.

As the long film, single films or laminated films of polyethylene terephthalate, polybutylene terephthalate, polyamide, polyvinyl chloride, polycarbonate, polystyrene, polypropylene, polyethylene, and the like are generally used. When a long film formed of an insulating polymer material is delivered from a supply roll, the long film is often charged with static electricity. The charge voltage of the long film reaches several tens of thousands of volts.

When the guide roll on the delivery side has the same potential as that of a vacuum chamber, static electricity charged on the long film delivered from the supply roll may be discharged to the guide roll to damage the long film.

Usually, for preventing discharge, ions are supplied to the long film between the supply roll and the guide roll by an electricity removing apparatus (ion generating apparatus) to remove charges on the long film. However, when the long film is conveyed at a high speed, removal of electricity may be incomplete.

JP-A-2009-19246 describes that “a guide roll in contact with a conductive thin layer on a long film is isolated from a vacuum chamber and kept at a floating potential”. In the sputtering method, charged particles in plasma enters a conductive thin layer, so that the conductive thin layer is charged. If the guide roll is grounded, a current passes through the conductive thin layer to generate Joule heat, so that a film on which the conductive thin layer is formed is thermally stretched. In JP-A-2009-19246, it is not necessary to keep a guide roll, which is not in contact with a conductive thin layer, at a floating potential.

The long film is charged not only when the long film is delivered from the supply roll. Unlike Joule heat cited as the problem in JP-A-2009-19246, discharge of static electricity occurs even when the long film is not provided with conductive thin layer. Therefore, the long film may discharge static electricity to all guide rolls. Thus, if ion electricity removing apparatuses are used, electricity removing apparatuses must be installed on all guide rolls. In the case of a large-scale sputtering device, there are more than 100 guide rolls, so that the number of electricity removing apparatuses increases, and it is difficult to provide spaces for installing electricity removing apparatuses.

### SUMMARY OF THE INVENTION

It is an object of the present invention to provide a sputtering device capable of preventing discharge of static electricity charged on a long film to a guide roll, and a method for producing a long film with a thin layer in which discharge of static electricity from a long film to a guide roll is prevented.

The summary of the present invention is described as below.

(1) The sputtering device of the present invention is configured to form a thin layer on a long film. In a first preferred aspect, a sputtering device according to the present invention includes: a vacuum chamber; a vacuum pump for evacuating the vacuum chamber; a supply roll for supplying a long film; a storage roll for storing the long film; a film depositing roll that is provided in the vacuum chamber and conveys the long film along a surface thereof; a target facing the film depositing roll; a gas pipe for supplying a gas into the vacuum chamber; a plurality of guide rolls for guiding the long film; a plurality of guide roll shafts provided at each of both ends of the plurality of guide rolls; a plurality of bearings for supporting the plurality of guide roll shafts; and an insulator configured to insulate each guide roll shaft and each bearing from each other, in which contact surfaces of the guide rolls with the long film are kept at a floating potential.

(2) The sputtering device of the present invention is configured to form a thin layer on a long film. In a second preferred aspect, a sputtering device according to the present invention includes: a vacuum chamber; a vacuum pump for evacuating the vacuum chamber; a supply roll for supplying a long film; a storage roll for storing the long film; a film depositing roll that is provided in the vacuum chamber and conveys the long film along a surface thereof; a target facing the film depositing roll; a gas pipe for supplying a gas into the vacuum chamber; a plurality of guide rolls for guiding the long film; and a plurality of insulators configured to insulate and cover contact surfaces of the plurality of guide rolls with the long film, in which the contact surfaces of the guide rolls with the long film are kept at a floating potential.

(3) In a third preferred aspect, a method for producing a long film with a thin layer according to the present invention includes a step of conveying a long film in a vacuum chamber using guide rolls, in which contact surfaces of the guide rolls with the long film are kept at a floating potential.

(4) In a fourth preferred aspect of the method for producing a long film with a thin layer according to the present invention, each of the guide rolls includes: a plurality of guide roll shafts provided at each of both ends of each guide roll; a plurality of bearings for supporting the plurality of guide roll shafts; and a plurality of insulators configured to insulate the guide roll shafts and the plurality of bearings from each other, and a contact surface of each of the guide rolls with the long film is kept at a floating potential.

(5) In a fifth preferred aspect of the method for producing a long film with a thin layer according to the present invention, each of the guide rolls includes: an insulator configured to insulate and cover a contact surface of the guide roll with the long film, and the contact surface of the guide roll with the long film is kept at a floating potential.

In the sputtering device of the present invention, static electricity is not discharged from a long film to a guide roll even when the long film is charged with static electricity. The long film is thereby prevented from being damaged by discharge.

In the method for producing a long film with a thin layer according to the present invention, the long film is conveyed using a plurality of guide rolls kept at a floating potential, and therefore static electricity is not discharged from the long film to the guide rolls even when the long film is charged with static electricity. The long film is thereby prevented from being damaged by discharge.

Each of the guide rolls, in which a contact surface of the guide roll with a long film is kept at a floating potential, is hereinafter referred to as an “insulating guide roll”. When a conductive layer is formed on the long film, the conductive layer-formed surface of the long film becomes conductive. However, guidance of the conductive long film by the insulating guide roll causes no particular problem because the long film is not damaged.

For a full understanding of the present invention, reference should now be made to the following detailed description of the preferred embodiments of the invention as illustrated in the accompanying drawings.

### BRIEF DESCRIPTION OF THE DRAWINGS

FIG. 1 is a perspective view of a whole of a sputtering device of the present invention; and

FIG. 2 (a) is a perspective view of a first example of an insulating guide roll to be used in the present invention, and FIG. 2 (b) is a perspective view of a second example of an insulating guide roll to be used in the present invention.

### DESCRIPTION OF THE PREFERRED EMBODIMENTS

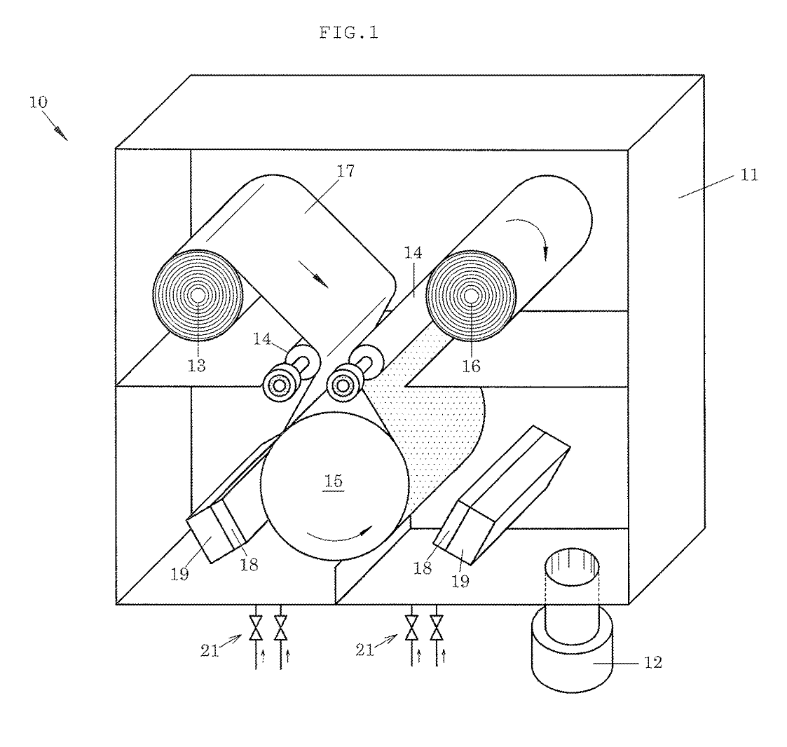

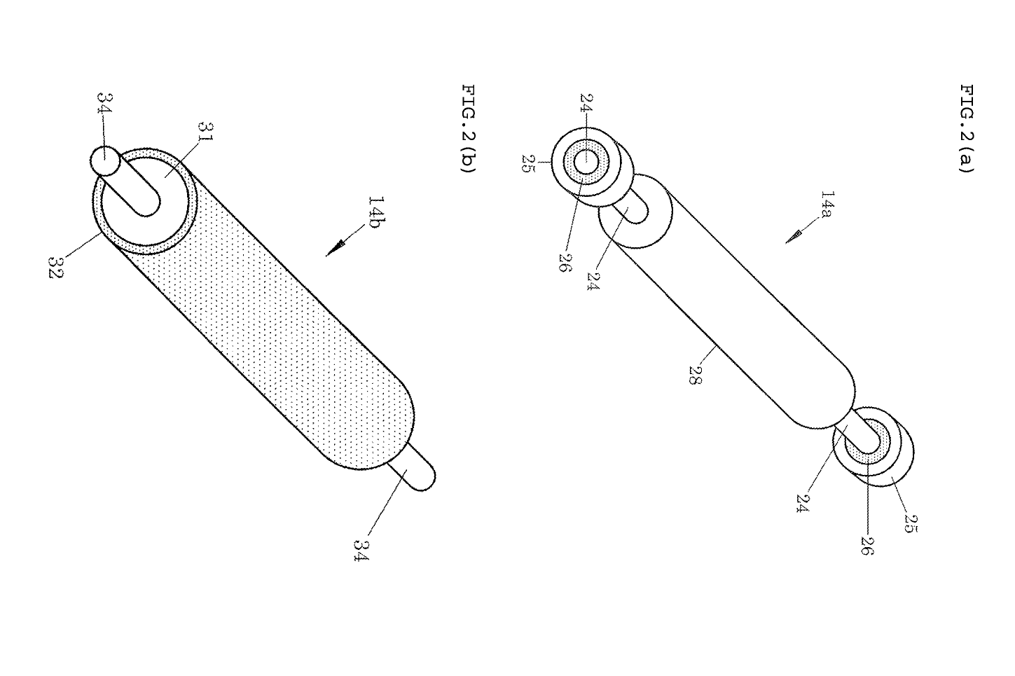

The preferred embodiments of the present invention will now be described with reference to FIGS. 1 to 2. Identical elements in the figure are designated with the same reference numerals.

FIG. 1 is a perspective view of the whole of one example of a sputtering device 10 of the present invention. The sputtering device 10 of the present invention includes a vacuum chamber 11, and a vacuum pump 12 for evacuating the vacuum chamber 11. A supply roll 13, an insulating guide roll 14, a film depositing roll 15, and a storage roll 16 are provided in the vacuum chamber 11. A long film 17 is delivered from the supply roll 13, guided by the insulating guide roll 14, wound around the film depositing roll 15 by less than one round, guided again by the insulating guide roll 14, and stored in the storage roll 16. A target 18 faces the film depositing roll 15 with a predetermined distance therebetween. On the long film 17 continuously running over the film depositing roll 15, sputtered layers are formed so as to face the target 18. While FIG. 1 illustrates two targets 18, the number of targets 18 is not limited. A gas pipe 21 for supplying a sputtering gas (e.g., argon gas) and a reactive gas (e.g., oxygen gas) is provided between the target 18 and the film depositing roll 15.

In the sputtering device 10 of the present invention, plasma of sputtering gas is generated by applying a voltage between the film depositing roll 15 and the target 18 with the film depositing roll 15 kept at an anodic potential and the target 18 kept at a cathodic potential in a sputtering gas such as a low-pressure argon gas. Sputtering gas ions in the plasma strike the target 18, so that a constituent material of the target 18 is driven out. The constituent material of the target 18, which is driven out, is deposited on the long film 17 to form a thin layer. The film depositing roll 15 is controlled to a constant temperature within a range of, for example, 20° C. to 250° C. for obtaining a film of high quality.

As a transparent conductive layer, a thin layer of indium-tin-oxide (ITO) is widely used. When a thin layer of an oxide such as indium-tin-oxide (ITO) is formed, a reactive sputtering method is used. In the reactive sputtering method, a reactive gas such as oxygen is supplied in addition to a sputtering gas such as argon. In the reactive sputtering method, the constituent material of the target 18, which is driven out, reacts with a reactive gas, so that the constituent material of the target 18, such as an oxide, is deposited on the long film 17.

In the sputtering device 10 of the present invention, the target 18 and a cathode 19 are mechanically and electrically integrated. The long film 17 and the target 18 face each other with a predetermined distance therebetween. The sputtering gas and the reactive gas are supplied between the long film 17 and the target 18. The sputtering gas and the reactive gas may be supplied separately, or may be supplied in mixture.

FIG. 2 (a) is a perspective view of a first example of an insulating guide roll 14a to be used in the sputtering device 10 of the present invention. FIG. 2 (b) is a perspective view of a second example of an insulating guide roll 14b to be used in the sputtering device 10 of the present invention.

The insulating guide roll 14a in FIG. 2 (a), a plurality of guide roll shafts 24, and a plurality of bearings 25 for supporting the plurality of guide roll shafts 24 are insulated from each other by a plurality of doughnut-shaped insulators 26, and a contact surface of a guide roll 28 with the long film 17 is kept at a floating potential. The plurality of bearings 25 are kept at a potential equal to that of the vacuum chamber 11. The guide roll 28 and the guide roll shafts 24 of the insulating guide roll 14a are metal (e.g., one obtained by plating a surface of an aluminum cylinder with hard chromium). Thus, a contact surface of the guide roll 28 with the long film 17 is metal (e.g., hard chromium-plated surface).

However, since the guide roll 28 and the guide roll shafts 24 are kept at a floating potential, the contact surface with the long film 17 is also kept at a floating potential. Therefore, even when the charged long film 17 comes into contact with the insulating guide roll 14a, static electricity is not discharged from the long film 17 to the insulating guide roll 14a. Therefore, the long film 17 is not damaged by discharge.

As a material of the doughnut-shaped insulator 26 inserted between the guide roll shaft 24 and the bearing 25, a polyether ether ketone material (PEEK (registered trademark)) as an engineering plastic is suitable in view of dielectric strength voltage and mechanical strength.

In the insulating guide roll 14b in FIG. 2 (b), the surface of a guide roll 31 is covered with an insulator 32, and the contact surface with the long film 17 is kept at a floating potential. The guide roll 31 and a plurality of guide roll shafts 34 are metal (e.g., aluminum), and therefore kept at a potential equal to that of the vacuum chamber 11.

However, since the contact surface with the long film 17 is covered with the insulator 32, static electricity is not discharged from the long film 17 to the insulating guide roll 14b even when the charged long film 17 comes into contact with the insulating guide roll 14b. Therefore, the long film 17 is not damaged by discharge.

As a material of the insulator 32 for covering the surface of the guide roll 31, a ceramic spray layer of aluminum oxide, silicon nitride, or the like is suitable in view of dielectric strength voltage and ease of forming a layer.

The long film 17 is easily charged when the long film 17 is delivered from the supply roll 13. However, the long film 17 may be charged not only at the time of delivery, but also in a conveyance path of the long film 17. In a large-scale sputtering device, 100 or more guide rolls are used. Since the long film 17 is damaged when discharge occurs in any of the guide rolls, it is preferable to use insulating guide rolls 14a or 14b for all of the guide rolls.

A method for producing a long film with a thin layer according to the present invention will now be described in detail. In the vacuum chamber 11 in FIG. 1, the insulating long film 17 is delivered from the supply roll 13, guided by the insulating guide roll 14, and wound around the film depositing roll 15 by less than one round. For example, a transparent conductive layer is formed on a portion of the long film 17 which faces the target 18, while the film depositing roll 15 is rotated at a constant speed to cause the long film 17 to run at a constant speed. The long film 17 after completion of film deposition is guided by the insulating guide roll 14 on the storage side and wound around the storage roll 16. The film depositing roll 15 is controlled to a constant temperature within a range of, for example, 20° C. to 250° C. for obtaining a film of high quality.

At the time of sputtering, a direct-current voltage (or alternating-current voltage) is applied between the film depositing roll 15 and the target 18 to generate plasma of sputtering gas (e.g., argon gas). The direct-current voltage is, for example, 0 V (earth potential) for the film depositing roll 15 and −400 V to −100 V for the target 18. Sputtering gas ions are caused to strike the target 18, and a material (e.g., indium atom or tin atom) of the target 18 which is scattered from the target 18 is deposited on the long film 17.

When the insulating long film 17 is delivered from the supply roll 13, the long film 17 is often charged with static electricity. When the guide roll on the delivery side is in conduction with the vacuum chamber 11 and is kept at an earth potential, static electricity charged on the long film delivered from the supply roll may be discharged to the guide roll to damage the long film.

However, in the method for producing a long film with a thin layer according to the present invention, the long film 17 is guided by the insulating guide roll 14, and therefore even when the long film 17 is charged, there is no possibility that the charge may be discharged to the insulating guide roll 14. Therefore, the long film 17 is prevented from being damaged by discharge.

When the long film 17 is in contact with the insulating guide roll 14 on the storage side, a surface on the transparent conductive layer side is not charged because a transparent conductive layer is formed on the long film 17. However, there is no particular problem even when the guide roll on the storage side is the insulating guide roll 14.

### INDUSTRIAL APPLICABILITY

The sputtering device and the sputtering method of the present invention are useful for forming a thin layer, particularly, a transparent conductive layer of indium-tin-oxide (ITO) or the like, on a long film.

This application claims priority from Japanese Patent Application No. 2013-150055, which is incorporated herein by reference.

There have thus been shown and described a novel sputtering device and a novel method for producing a long film with thin layer which fulfill all the objects and advantages sought therefor. Many changes, modifications, variations and other uses and applications of the subject invention will, however, become apparent to those skilled in the art after considering this specification and the accompanying drawings which disclose the preferred embodiments thereof. All such changes, modifications, variations and other uses and applications which do not depart from the spirit and scope of the invention are deemed to be covered by the invention, which is to be limited only by the claims which follow.

What is claimed is:

1. A sputtering device configured to form a thin layer on a long film, the sputtering device comprising:
a vacuum chamber;
a vacuum pump for evacuating the vacuum chamber;
a supply roll for supplying the long film;
a storage roll for storing the long film;
a film depositing roll that is provided in the vacuum chamber and conveys the long film along a surface thereof;
a target facing the film depositing roll;
a gas pipe for supplying a gas into the vacuum chamber;
a plurality of guide rolls for guiding the long film;
a plurality of guide roll shafts provided at each of both ends of the plurality of guide rolls;
a plurality of bearings for supporting the plurality of guide roll shafts; and
a plurality of insulators configured to insulate the guide roll shafts and the plurality of bearings from each other,
wherein contact surfaces of the guide rolls with the long film are kept at a floating potential.

2. A sputtering device configured to form a thin layer on a long film, the sputtering device comprising:
a vacuum chamber;
a vacuum pump for evacuating the vacuum chamber;
a supply roll for supplying the long film;
a storage roll for storing the long film;
a film depositing roll that is provided in the vacuum chamber and conveys the long film along a surface thereof;
a target facing the film depositing roll;
a gas pipe for supplying a gas into the vacuum chamber;
a plurality of guide rolls for guiding the long film; and
a plurality of insulators configured to insulate and cover contact surfaces of the guide rolls with the long film,
wherein the contact surfaces of the guide rolls with the long film are kept at a floating potential.

3. A method for producing a long film with a thin layer, comprising a step of conveying a long film in a vacuum chamber using a plurality of guide rolls, in which contact surfaces of the guide rolls with the long film kept at a floating potential.

4. The method for producing a long film with a thin layer according to claim 3, wherein each of the guide rolls includes:
a plurality of guide roll shafts provided at each of both ends of the plurality of guide rolls;
a plurality of bearings for supporting the plurality of guide roll shafts; and
a plurality of insulators configured to insulate the guide roll shafts and the bearings from each other,
wherein contact surfaces of the guide rolls with the long film are kept at a floating potential.

5. The method for producing a long film with a thin layer according to claim 3, wherein each of the guide rolls includes:
a plurality of insulators configured to insulate and cover contact surfaces of the guide rolls with the long film,
wherein the contact surfaces of the guide rolls with the long film are kept at a floating potential.
